(19) United States
(12) Patent Application Publication
(10) Pub. No.: US 2014/0035787 A1
(43) Pub. Date: Feb. 6, 2014

(54) Antenna System

(71) Applicant: WFS Technologies Limited, Edinburgh (GB)

(72) Inventors: Brendan Peter Hyland, Edinburgh (GB); John Roulston, Edinburgh (GB)

(21) Appl. No.: 13/910,345

(22) Filed: Jun. 5, 2013

(30) Foreign Application Priority Data
Aug. 6, 2012 (GB) 1210151.5

(51) Int. Cl. G01R 29/08; G01R 33/07

(52) U.S. Cl. CPC G01R 29/0878; G01R 33/07
USPC 343/720

(57) ABSTRACT

An antenna system for us in detecting electromagnetic and/or magneto inductive said antenna system further comprising at least two semi-conductor sensor arrays operable to detect in magnetic field component of the electromagnetic and/or magneto-inductive signals, the arrays arranged to be operable for tri-axial detection of the magnetic field component; at least two output means where an output means is associated with each sensor array and operable to output a signal indicative of the detected magnetic field; and detection means operable to receive said sensor array outputs and operable to act upon said received outputs to generate a signal indicative of the detected electromagnetic and/or magneto-inductive signal.

### CROSS-REFERENCE TO RELATED APPLICATIONS

This application claims the benefit of GB 1210151.5 filed Jun. 8, 2012, which application is fully incorporated herein by reference.

### INTRODUCTION

The present invention relates to an antenna system and in particular to an antenna system using semi-conductor sensor arrays for detecting a magnetic field component of an electromagnetic signal.

### BACKGROUND

Semiconductor magnetic field sensors such as Hall Effect sensors are known to have applications in magnetic compassing, current sensing and the like with a change in magnetic field providing a varied output from the sensor device.

In particular these semiconductor sensors are used for applications such as counting and limit switches which provide a DC output from the sensor which is operable to implement a counting or limit switch function. In addition, Hall Effect sensors have been used as data transmitters and receivers. For example, in US48484071, Hall Effect sensors are used in communication systems in a well bore to receive data across the junction of connected well bore tools components.

Whilst the use of a Hall Effect sensor in this communication system arrangement provides effective communication, such uses are limited as the two parts of the communications system, namely the transmitter and receiver, must be in alignment for the sensor to work effectively. In a constrained environment such as a well bore tool, this communications technique is of great value. However, these communication systems have limited utility for more general use in data communication systems as, without alignment between transmitter and receiver, inadequate reception of data will occur as the Hall Effect sensor will only receive the signal in one axis.

It is therefore an object of the present invention to provide a semiconductor magnetic field sensor antenna system operable to detect a magnetic field component in more than one axis.

According to a first aspect of the invention there is provided an antenna system for use in detecting electromagnetic and/or magneto inductive signals, said antenna system comprising at least two semiconductor sensor arrays operable to detect in magnetic field component of the electromagnetic and/or magneto-inductive signals, the arrays arranged to be operable for tri-axial detection of the magnetic field component; at least two output means wherein an output means is associated with each sensor array and operable to output a signal indicative of the detected magnetic field; and detection means operable to receive said sensor array outputs and to act upon said received outputs to generate a signal indicative of the detected electromagnetic and/or magneto-inductive signal.

By providing an antenna array formed of semiconductor sensor arrays having the form of at least a half cylinder magnetic field signals in two directions will be detectable and combining this with a third orthogonally arranged array, a tri-axial sensor will be obtained. As the sensor arrays are operable to detect the magnetic field of a magnetic signal tri-axially, the orientation of the antenna system has no limiting impact on the signal detection capability of the sensor arrays and antenna systems as a whole.

Preferably the antenna system is operable to be a radio frequency antenna system.

The magnetic field sensors may be operable to detect both near and propagating electromagnetic fields in the low frequency range of 2 Hz to 3 kHz.

By being operable in the noted frequency range the antenna system is suitable for use in an underwater environment in particular and can facilitate ultra low, very low frequency and low frequency radio communication through water and other fluids.

Each sensor array may be formed of at least one Hall Effect sensor.

The use of a Hall Effect sensor can provide the antenna system with the transmission and reception sensitivity equivalent to that found in a solenoid and thus a compact and effective alternative to traditional antenna arrangement, whilst also facilitating data communication.

Each sensor array may be formed of a plurality of Hall Effect sensors.

An array of Hall Effect sensors used as an antenna provides a noise advantage over the use of a coil antenna arrangement. In a coil antenna the sensitivity of antenna increase as the frequency increases. However, the effect of noise on the coil antenna also increases at the same rate. In the case of Hall Effect sensors the effect of noise is less marked and indeed a √N noise advantage is obtained as when the frequency increases as above 500 Hz, the noise is limited by Johnson noise. Therefore such an antenna system or device comprising an array of these Hall effects sensors is not a frequency dependent device.

Each Hall Effect sensor may be a Gallium Arsenide Sensor (GaAs). Alternatively each Hall Effect sensor may be a Gallium Arsenide Indium Hall Effect Sensor (GaAsIn). Such sensors may provide advantages in operational speed, reduced power consumption and efficient manufacturing and processing.

Preferably, the antenna system is operable for use in an NC communications system. Such an arrangement is advantageous in that it facilitates effective data transmission in the radio frequency range.

The antenna system may comprise at least three sensors arrays operable to detect the magnetic field of the electromagnetic signals, with each array arranged perpendicular to each other array; at least three output means with an output means associated with each sensor array and operable to output a signal indicative of the detected magnetic field, and detection means operable to receive said sensor array, output and operable to act upon said received sensor array output to generate a signal indicative of detected electromagnetic signal.

By providing at least three sensor arrays arranged perpendicular to one another wherein the sensor arrays are operable to detect the magnetic field of an magnetic signal, the orientation of the antenna system has no limiting impact on the signal detection capability of the sensor arrays and antenna systems as a whole.

The antenna system may further comprise six sensor arrays arranged to form an antenna system cube. Such an antenna system provides a sophisticated tri-axial sensor which enables use in sensing electromagnetic signals transmitted from any predetermined location.

The antenna system may further be operable for one of the transmission and reception of electromagnetic data carrying signals.

At least one array may be arranged upon a flexible substrate or at least one array may be arranged upon a rigid substrate.

According to a second aspect of the invention there is provided a transmitter including an antenna system of the first aspect of the invention.

According to a third aspect of the invention there is a provided a receiver including an antenna system in accordance with the first aspect of the invention.

According to a fourth aspect of the invention there is provided a transmission system wherein at least one of the transmitter of the second aspect of the invention and/or receiver of the third aspect of the invention is operable to communicate using data communication signals in the electromagnetic range wherein at least one of the transmitter and/or receiver comprises an antenna system in accordance with the first aspect the invention.

### BRIEF DESCRIPTION OF THE DRAWINGS

The present invention will now be described, by way of example only, with reference to the accompanying drawings in which:

FIG. 1a shows a schematic plan view of a sensor array according to a first embodiment of the present invention;

FIG. 1b shows a schematic cross section of the sensor array FIG. 1a;

FIG. 2 shows a block diagram of an antenna system according to a second embodiment of the present invention;

FIG. 3 shows a schematic diagram of an antenna system according to a third embodiment of the present invention, and

FIG. 4 shows a schematic diagram of a transmission system according to a fourth embodiment of the present invention.

### DESCRIPTION OF THE PREFERRED EMBODIMENTS

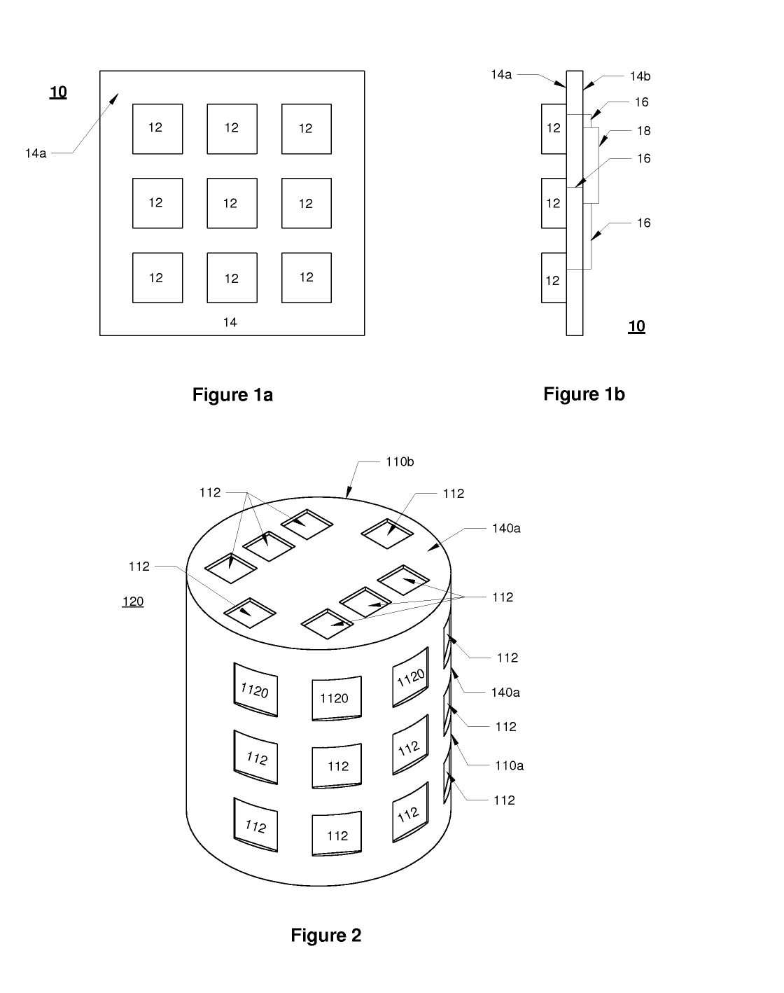

Reference is made initially to FIG. 1a of the drawings which illustrates a plan view of a sensor array 10 and FIG. 1b which shows a cross section view of sensor array 10. Sensor array 10 comprises a plurality of semiconductor sensors 12, in this case nine Hall Effect sensors, arranged upon the top surface 14a of substrate 14 which in this case is a flexible substrate. As can be seen in FIG. 1b each Hall Effect sensor 12 is provided with an output 16 which is connected to detection means 18 which in this case is arranged on the back 14b of substrate 14. This array of sensors 12 would, in use, be operable to detect a magnetic field (not shown) travelling perpendicular to the top surface 14a of substrate 14.

Each of the sensors 12 are, in this case, a gallium arsenide (GaAs) Hall Effect sensor. These sensors 12 have a transmission and receive sensitivity for detection of a magnetic field which is equivalent to that of a solenoid whilst providing a √N noise advantage over a corresponding solenoid are addition above the range of 500 Hz the noise effect of the sensors is limited by Johnston noise. Therefore this sensor array 10, unlike a coil, does not have an issue with frequency dependent noise. In use upon detection of a magnetic field component of an electromagnetic signal, each Hall Effect sensor 12 will create a voltage and a current output indicative of the strength of magnetic field detected. One or both of the voltage and current created is transferred to detection means 8 via output 16. The detection means 18 is operable to utilise the received signals from output 16 in order to generate an output indicative of the detective electromagnetic signal.

In FIG. 2 there is shown a cylindrical antenna system 120 comprising senor arrays 110a formed on a flexible substrate 114a and sensor array 110b formed on a rigid substrate 114b. In this case array 110a is curved to form a cylinder and array 110b is placed as a “lid” on one end of cylindrical array 110a thus forming a tri-axial antenna array 120.

This tri-axial antenna array 120 is operable to detect magnetic field signals which occur in any given direction. These magnetic field signals may be the magnetic field components of electromagnetic field signals. Such a tri-axial arrangement of the sensor arrays 110a, 110b, and 110c facilitates the use of the antenna system 120 in environments where close alignment of the transmitter and the receiver is not necessarily possible.

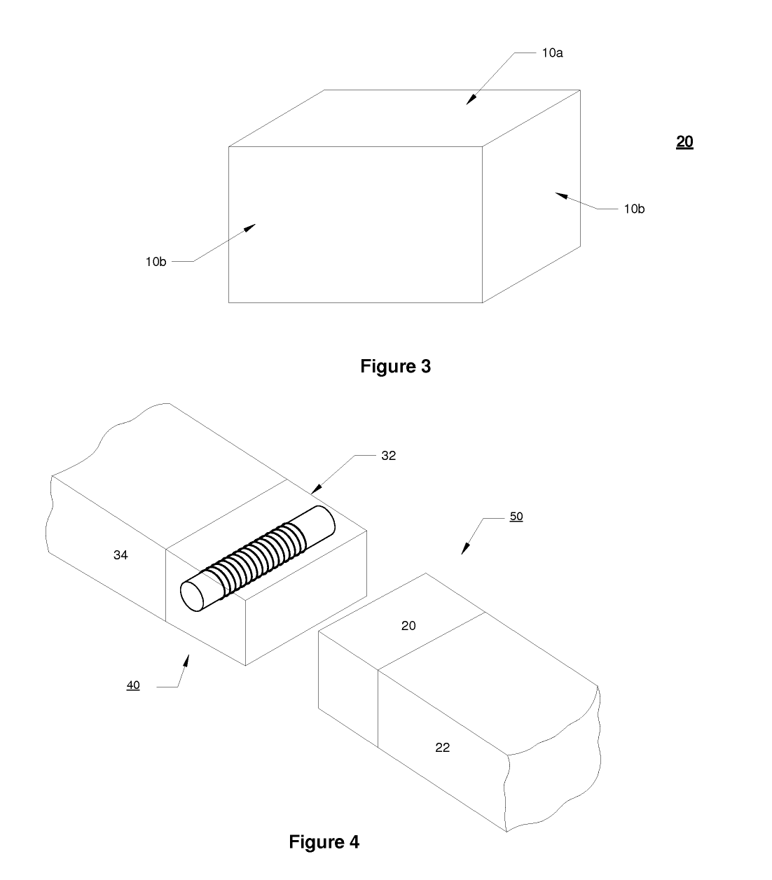

In FIG. 3 there is shown an antenna system cube 20 comprising sensor arrays 10a, 10b and 10c which are shown as well as sensor 10d, 10e, and 10f which cannot be seen, to form a cube structure. In this case the substrate of each sensor array is a rigid structure. By arranging these magnetic field sensors array 10a-10d in the form of a cube a tri-axial antenna arrangement is created.

This tri-axial antenna array 20 is operable to detect magnetic field signals which occur in any given direction. These magnetic field signals may be the magnetic field components of electromagnetic field signals. Such a tri-axial arrangement of the sensor arrays 10a, 10b, and 10c facilitates the use of the antenna system 20 in environments where close alignment of the transmitter and the receiver is not necessarily possible.

With reference to FIG. 4 there is shown a transmission system 50 comprising a transmitter arrangement 40 and a receiver arrangement 50. The transmission arrangement 40 comprises a transmitter unit 34 in communication with an antenna unit 32. The antenna unit 32 is operable to output a signal as an electromagnetic signal as directed by transmitter unit 34 and this output signal may carry data. This electromagnetic signal may be transmitted through any fluid such as air or water. The receiver unit 50 comprises the cube sensor 20 of FIG. 2 arranged to be in communication with receiver unit 24. The Hall effect cube sensor 20 is operable to detect the magnetic component of the transmitted electromagnetic signal. Upon detection of the magnetic field component of the transmitted signal each array in the cube sensor 2 provides an output which is provided via detection means 18 to receiver 24 wherein the receiver 24 can act upon the received output data in order to generate a received signal.

The principal advantage of the present invention is that it provides an antenna arrangement which can detect the magnetic field component of a signal in any of the three axes thus increasing utility and performance of the antenna system in a wide variety of operational environments.

A further advantage of the present invention is that it provides an antenna sensor which has improved noise performance and thus increase sensitivity and detection.

Various modifications may be made to the invention herein described without departing from the scope therein. For example, whilst a cube sensor having six sensor arrays arranged to form the cube structure has been described with reference to FIG. 2 it will be understood that a sensor arrangement comprising three sensor arrays arranged orthogonally would similarly work in a tri-axial manner. Alternatively should the substrate 14 be a flexible material the antenna system may be formed as a cylindrical body having orthogonal tops and bottoms and arrangement which also would be able to operate in a tri-axial manner. Also whilst the semiconductor sensor 12 has been described as a GaAs sensor any suitable semiconductor may be used including for example Gallium Arsenide Indium (GaAsIn). Furthermore, whilst cylindrical array 120 of FIG. 2 is shown as a full cylinder however it will be appreciated that any suitable degree of curvature that enables receipt in two axes would be sufficient.

1. An antenna system for us in detecting electromagnetic and/or magneto inductive said antenna system further comprising:
at least two semi-conductor sensor arrays operable to detect in magnetic field component of the electromagnetic and/or magneto-inductive signals, the arrays arranged to be operable for tri-axial detection of the magnetic field component;
at least two output means where an output means is associated with each sensor array and operable to output a signal indicative of the detected magnetic field; and
detection means operable to receive said sensor array outputs and operable to act upon said received outputs to generate a signal indicative of the detected electromagnetic and/or magneto-inductive signal.

2. An antenna system as claimed in claim 1 wherein the antenna system is operable to be a radio frequency antenna system.

3. An antenna system as claimed in claim 1 wherein the antenna system is operable to work under water.

4. An antenna system as claimed in claim 1 wherein each sensor array is formed off at least one Hall effect sensor.

5. An antenna system as claimed in claim 4 wherein each sensor array is formed of a plurality of Hall effect sensors.

6. An antenna system as claimed in claim 4 wherein each Hall effect sensor is a gallium arsenide sensor.

7. An antenna system as claimed in claim 4 wherein each Hall effect sensor is a gallium arsenide indium Hall effect sensor.

8. An antenna system as claimed in claim 1 wherein the antenna system is operable for use in an AC communication system.

9. An antenna system as claimed in claim 1 comprising at least one sensor array curved to form at least a half cylinder and at least one other sensor array arranged orthogonally to straight edge of the curved array.

10. An antenna system as claimed in claim 1 operable for use in detecting electromagnetic said antenna, said antenna system further comprising:
at least three semi-conductor sensor arrays operable to detect in magnetic field component of the electromagnetic and/or magneto-inductive signals, each array arranged to be perpendicular to each other array;
at least three output means where an output means is associated with each sensor array and operable to output a signal indicative of the detected magnetic field; and
detection means operable to receive said sensor array outputs and operable to act upon said received outputs to generate a signal indicative of the detected electromagnetic and/or magneto-inductive signal

11. An antenna system as claimed in claim 10 comprising six sensor arrays arranged to form an antenna system cube.

12. An antenna system as claimed in claim 1 operable for use in one of the transmission and reception of electromagnetic and/or magneto-inductive data carrying signals.

13. An antenna system is claim in claim 1 wherein at least one array is arranged upon a flexible substrate.

14. An antenna system is claim in claim 1 wherein at least one array is arranged upon a rigid substrate.

15. A transmitter comprising an antenna system as detailed in claim 1.

16. A receiver comprising an antenna system as claimed in claim 1.

17. A transmission system comprising at least one transmitter and at least one receiver, wherein at least of the transmitter and the receiver includes an antenna system as claimed in claim 1 and the other of the at least transmitter and receiver includes an electromagnetic and/or magneto-inductive antenna.
